(19) United States
(12) Patent Application Publication
(10) Pub. No.: US 2023/0008795 A1
(43) Pub. Date: Jan. 12, 2023

(54) METHOD FOR MANUFACTURING MICRO LED DISPLAY

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 17/779,551

(22) PCT Filed: Oct. 19, 2020
(86) PCT No.: PCT/KR2020/014208

§ 371 Date: May 24, 2022

(30) Foreign Application Priority Data
Nov. 25, 2019 (KR) 10-2019-0152077

(51) Int. Cl. H01L 33/00; H01L 25/075

(52) U.S. Cl. CPC H01L 33/0095; H01L 25/0753

(57) ABSTRACT

Proposed is a method for manufacturing a micro LED display, the method including a step of preparing a plurality of first substrates having a plurality of micro LEDs, respectively, a step of preparing a plurality of second substrates, a segmented region formation step of segmenting each of the first substrates into a plurality of regions, and a step of transferring micro LEDs of one segmented region of each of the first substrates to an associated one of the second substrates, wherein the one second substrate comprises the micro LEDs of the first substrate.

### BACKGROUND

### Technical Field

The present disclosure relates generally to a method for manufacturing a micro LED display. More particularly, the present disclosure relates to a method for manufacturing a micro LED display in which the region of a first substrate is segmented and micro LEDs of segmented regions thereof are transferred to a second substrate in different arrangement such that non-uniformity of luminous properties is prevented.

### Description of Related Art

Currently, the display market is still dominated by LCDs, but OLEDs are quickly replacing LCDs and emerging as mainstream products. In a current situation where display makers are rushing to participate in the OLED market, a micro LED display (hereinafter referred to as “a micro LED”) has emerged as another next generation display. Liquid crystal and organic materials are the core materials of LCDs and OLEDs, respectively, whereas the micro LED display uses 1 μm to 100 μm of an LED chip itself as a light emitting material.

Since the term “micro LED” emerged when Cree Inc. applied for a patent for “MICRO-LED ARRAYS WITH ENHANCED LIGHT EXTRACTION” in 1999 (Korean Patent No. 10-0731673), related research papers have been subsequently published, and R&D is being carried out. In order to apply micro LEDs to a display, it is necessary to develop a customized microchip based on a micro LED element made of a flexible material and/or flexible element, and the techniques of transferring micrometer-sized LED chips and accurately mounting the LED chips on a display pixel electrode are required.

After a micro LED is manufactured on a growth substrate, the micro LED is transferred to a circuit board through a transfer head. In this case, the micro LED may go through a temporary substrate before being transferred from the growth substrate to the circuit board.

A micro LED may be formed on the growth substrate by using methods such as metal organic chemical vapor deposition (MOCVD), chemical vapor deposition (CVD), plasma-enhanced chemical vapor deposition (PECVD), molecular beam epitaxy (MBE), and hydride vapor phase epitaxy (HYPE), etc. In this case, luminous wavelength or luminous efficiency may vary greatly depending on the thickness and composition (In composition ratio) of the p and n-type semiconductor layers of the micro LED.

However, when a micro LED is formed on the growth substrate, it is difficult to uniformly maintain temperature distribution or flow of raw material carrier gas, which are parameters of the thickness or composition of the p-type semiconductor layer and the n-type semiconductor layer, within the growth substrate. Accordingly, a micro LED formed on the growth substrate may have non-uniform luminous properties. In this case, the luminous properties refer to luminous chromaticity, luminous wavelength, luminance, ratio of luminance of the oblique direction to front direction, and rate of change of luminance with respect to temperature change.

When micro LEDs having non-uniform luminous properties are simultaneously transferred from the growth substrate to the corresponding position of the temporary substrate or the circuit board, a display manufactured through the temporary substrate or the circuit board has color non-uniformity or luminance non-uniformity. Accordingly, as the picture quality of the display deteriorates, practicality thereof may deteriorate.

As a patent for preventing the non-uniformity of luminous properties of a micro LED, Japanese patent application publication No. 2010-251360 (hereinafter, referred to as “related art 1”) is disclosed.

A method of manufacturing a display of the related art 1 is a technology in which light emitting elements (micro LEDs) in a specific position on a first substrate are simultaneously transferred to a second substrate, the arrangement of the light emitting elements the first substrate and the arrangement of the light emitting elements of the second substrate are different to prevent non-uniformity of luminous properties of the light emitting elements.

However, in the method of manufacturing a display of the related art 1, only predetermined number of micro LEDs of the first substrate is transferred to the second substrate at a predetermined distance, and thus it takes a lot of time to transfer all micro LEDs of the first substrate to the second substrate.

### DOCUMENTS OF RELATED ART

### Patent Document

(Patent Document 1) Korean Patent No. 0731673

(Patent Document 2) Japan Patent Application Publication No. 2010-251360

### SUMMARY

### Technical Problem

Accordingly, the present disclosure has been made to solve the problems of the prior art, and the present disclosure is intended to propose a method for manufacturing a micro LED display in which the region of a first substrate is segmented and micro LEDs of segmented regions thereof are simultaneously adsorbed and transferred to a second substrate such that time required for the transferring is reduced.

In addition, the present disclosure is intended to propose a method for manufacturing a micro LED display in which micro LED arrangements of the first substrate and the second substrate are different from each other such that non-uniformity of luminous properties of micro LEDs is prevented.

### Technical Solution

In order to accomplish the above objectives of the present disclosure, a method for manufacturing a micro LED display according to the present disclosure includes: a step of preparing a plurality of first substrates having a plurality of micro LEDs; a step of preparing a plurality of second substrates; a segmented region formation step of segmenting each of the first substrates into a plurality of regions; and a step of transferring micro LEDs of each of the segmented regions of each of the first substrates to each of the second substrates, wherein one of the second substrates comprises micro LEDs of the plurality of first substrates.

In addition, the micro LEDs of each of the segmented regions of each of the first substrates may be sequentially transferred to a corresponding position of each of the second substrates.

Furthermore, the micro LEDs of each of the segmented regions of each of the first substrates may be sequentially transferred to a non-corresponding position of each of the second substrates.

### Advantageous Effects

As described above, in the method for manufacturing a micro LED display according to the present disclosure, the region of the first substrate is segmented and micro LEDs of segmented regions are simultaneously adsorbed and transferred to the second substrate, thereby reducing time required for the transferring.

In addition, micro LED arrangements of the first substrate and the second substrate are different from each other, thereby preventing non-uniformity of luminous properties of micro LEDs.

### BRIEF DESCRIPTION OF THE DRAWINGS

FIG. 1 is a view illustrating micro LEDs according to a first exemplary embodiment of the present disclosure.

FIG. 2 is a view illustrating a micro LED structure mounted on a circuit board.

FIG. 3 are views roughly showing the process of manufacturing a micro LED display, which is the background technology of the idea of the present disclosure.

FIG. 4 are views illustrating the appearances of a first substrate and a second substrate, respectively, according to the exemplary embodiment of the present disclosure.

FIG. 5 are views illustrating luminous properties of micro LEDs of the substrates of FIG. 4.

FIG. 6 are views illustrating the modified appearances of FIG. 4, respectively.

FIG. 7 are views illustrating the appearances of the first substrate and the second substrate of FIG. 4, respectively, according to a second embodiment.

### DESCRIPTION OF THE EMBODIMENTS

The following is merely illustrative of the principles of the invention. Therefore, although not explicitly described or shown herein, those skilled in the art will be able to devise various devices that embody the principles of the invention and fall within the spirit and scope of the invention. Additionally, all conditional terms and embodiments listed herein are expressly intended solely for the purpose of providing an understanding of the concept of the invention, and it should be understood that the conditional terms are not limited to the embodiments and states specifically enumerated.

The above objects, features and advantages will become more apparent through the following detailed description in relation to the accompanying drawings, and accordingly, those skilled in the technical field to which the invention belongs will be able to easily realize the technical idea of the invention.

Embodiments described in this specification will be described with reference to cross-sectional and/or perspective views, which are ideal illustrative views of the present disclosure.

The thickness of regions and the diameter of holes shown in these drawings are exaggerated for the effective description of technical content. The shapes of the illustrative drawings may be modified due to manufacturing technology and/or tolerance. In addition, only a part of the number of micro LEDs shown in the drawings is illustrated in the drawings. Accordingly, the embodiments of the present disclosure are not limited to illustrated specific forms, but also include a change in a form generated according to a manufacturing process.

In describing various embodiments, the same names and reference numerals are given to components performing the same functions for convenience even if the embodiments are different. Additionally, configurations and operations already described in other embodiments will be omitted for convenience.

Hereinafter, before describing exemplary embodiments of the present disclosure with reference to the accompanying drawings, a micro element may include a micro LED. A micro LED is cut from a wafer used for crystal growth without being packaged with molded resin, etc., and scientifically refers to a micro LED having a size of 1˜100 μm unit. However, a micro LED described herein is not limited to a size (length of one side) of 1 to 100 μm, and includes a micro LED having a size of 100 μm or more or a size of less than 1 μm.

In addition, configurations of the exemplary embodiments of the present disclosure described below may also be applied to the transferring of micro elements that can be applied without changing the technical idea of each of the embodiments.

Hereinafter, the exemplary embodiments of the present disclosure will be described in detail with reference to the accompanying drawings.

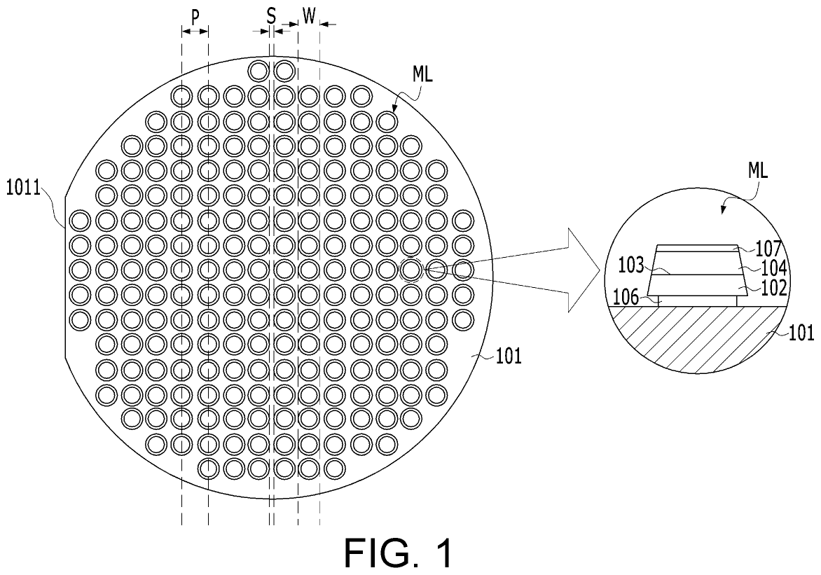

FIG. 1 is a view illustrating micro LEDs according to a first exemplary embodiment of the present disclosure.

Micro LEDs ML are manufactured and located on the first substrate 101. In this case, the first substrate 101 may be provided as a growth substrate.

The first substrate 101 may be configured as a conductive substrate or an insulating substrate. For example, the first substrate 101 may be formed of at least one of sapphire, SiC, Si, GaAs, GaN, ZnO, Si, GaP, InP, Ge, and Ga₂O₃. In the embodiment, it will be described as an example that the first substrate 101 is a growth substrate formed of sapphire and includes a curvature in at least a portion of an edge thereof.

A micro LED ML may include a first semiconductor layer 102, a second semiconductor layer 104, an active layer 103 formed between the first semiconductor layer 102 and the second semiconductor layer 104, a first contact electrode 106, and a second contact electrode 107.

The first semiconductor layer 102, the active layer 103, and the second semiconductor layer 104 may be formed by using methods such as metal organic chemical vapor deposition (MOCVD), chemical vapor deposition (CVD), plasma-enhanced chemical vapor deposition (PECVD), molecular beam epitaxy (MBE), and hydride vapor phase epitaxy (HYPE), etc.

For example, the first semiconductor layer 102 may be embodied as a p-type semiconductor layer. The material of the p-type semiconductor layer may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and AlInN, etc., and p-type dopants such as Mg, Zn, Ca, Sr, and Ba may be doped on the p-type semiconductor layer.

For example, the second semiconductor layer 104 may be formed by including the n-type semiconductor layer. The material of the n-type semiconductor layer may be selected from semiconductor materials having the composition formula of InₓAl_{y}Ga_{1-x-y}N (0≤x≤1, 0≤y≤1, 0≤x+y≤1), for example, GaN, AlN, AlGaN, InGaN, InN, InAlGaN, and AlInN, etc., and n-type dopants such as Si, Ge, and Sn may be doped on the n-type semiconductor layer.

However, the present disclosure is not limited to thereto, and the first semiconductor layer 102 may include the n-type semiconductor layer, and the second semiconductor layer 104 may include the p-type semiconductor layer.

The active layer 103 is a region in which electrons and holes recombine, and transitions to a low energy level as the electrons and holes recombine, and may generate light having a corresponding wavelength. For example, the active layer 103 may be formed by including semiconductor materials having the composition formula of InₓAl_{y}Ga_{1-x-y}N (0≤x≤1, 0≤y≤1, 0≤x+y≤1), and may be configured as a single quantum well structure or a multi quantum well (MQW) structure.

In addition, the active layer may include a quantum wire structure or a quantum dot structure. The first contact electrode 106 may be formed on the first semiconductor layer 102, and the second contact electrode 107 may be formed on the second semiconductor layer 104. The first contact electrode 106 and/or the second contact electrode 107 may include one layer or more and may be formed of a variety of conductive materials including metals, conductive oxides, and conductive polymers.

A plurality of micro LEDs ML formed on the first substrate 101 may be cut along a cutting line by using a laser or separated individually through an etching process, and may be made separable from the first substrate 101 by a laser lift-off process.

In FIG. 1, “P” means a pitch interval between micro LEDs ML, “S” means spacing distance between micro LEDs ML, and “W” means width of each of micro LEDs ML. In FIG. 1, the cross-sectional shape of a micro LED ML is exemplified as a circular shape with a curvature formed on a part of an edge thereof, but is not limited thereto, and may have cross-sectional shapes other than a circular cross-section, such as a square cross-section.

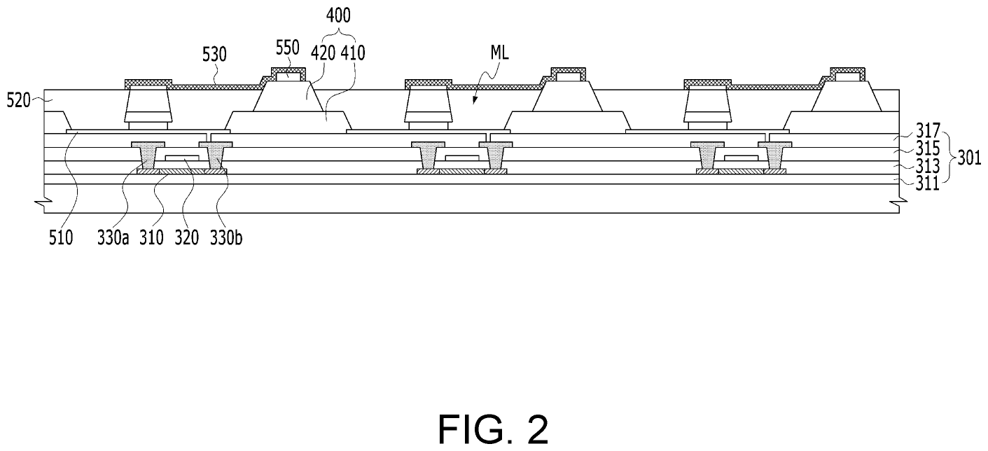

FIG. 2 is a view illustrating a micro LED structure mounted on a circuit board.

Referring to FIG. 2, a third substrate 301 may include various materials. For example, the third substrate 301 is the circuit board, and may be made of a transparent glass material containing SiO₂ as a main component. However, the third substrate 301 is not necessarily limited thereto, and may be formed of a transparent plastic material to have solubility. The plastic material may be an organic material selected from a group consisting of insulating organic materials such as polyethersulfone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), and cellulose acetate propionate (CAP).

In case in which a micro LED is a rear-emission type LED in which an image is embodied in a direction toward the third substrate 301, the third substrate 301 is required to be formed of a transparent material. However, in case in which a micro LED is a front-emission type LED in which an image is embodied in a direction opposite to the third substrate 301, the third substrate 301 is not required to be formed of a transparent material. In this case, the third substrate 301 may be formed of metal.

When the circuit board 301 is formed of metal, the circuit board 301 may include at least one selected from a group consisting of iron, chromium, manganese, nickel, titanium, molybdenum, stainless steel (SUS), Invar alloy, Inconel alloy, and Kovar alloy, but is not limited thereto.

The third substrate 301 may include a buffer layer 311. The buffer layer 311 may provide a flat surface and block the penetration of foreign matter or moisture. For example, the buffer layer 311 may contain an inorganic material such as silicon oxide, silicon nitride, silicon oxynitride, aluminum oxide, aluminum nitride, titanium oxide or titanium nitride, or an organic material such as polyimide, polyester, or acrylic, and may be formed of a plurality of laminates of the exemplified materials.

A thin film transistor (TFT) may include an active layer 310, a gate electrode 320, a source electrode 330a, and a drain electrode 330b.

Hereinafter, the thin film transistor (TFT) of a top gate type in which the active layer 310, the gate electrode 320, the source electrode 330a, and the drain electrode 330b are sequentially formed will be described. However, this embodiment is not limited thereto, but various types of thin film transistor (TFT) such as a bottom gate type of thin film transistor, etc. may be employed therein.

The active layer 310 may include a semiconductor material, for example, amorphous silicon or polycrystalline silicon. However, this embodiment is not limited thereto, and the active layer 310 may contain various materials. In an optional embodiment, the active layer 310 may contain an organic semiconductor material or the like.

In another optional embodiment, the active layer 310 may contain an oxide semiconductor material. For example, the active layer 310 may include oxides of materials selected from group 12, 13, and 14 metal elements such as zinc (Zn), indium (In), gallium (Ga), tin (Sn), cadmium (Cd), and germanium (Ge), and combinations thereof.

A gate insulating layer 313 is formed on the active layer 310. The gate insulating layer 313 may function to insulate the active layer 310 from the gate electrode 320. The gate insulating layer 313 may be configured as a single or multi-layered film made of an inorganic material such as silicon oxide and/or silicon nitride.

The gate electrode 320 is formed on the gate insulating layer 313. The gate electrode 320 may be connected to a gate line (not shown) that applies an on/off signal to the thin film transistor (TFT).

The gate electrode 320 may be made of a low-resistance metal material. In consideration of adhesion with an adjacent layer, surface flatness of a layer to be laminated, and workability, etc., the gate electrode 320, for example, may be configured as a single layer or multiple layers formed of at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An interlayer insulating film 315 is formed on the gate electrode 320. The interlayer insulating film 315 insulates the source electrode 330a and the drain electrode 330b from the gate electrode 320.

The interlayer insulating film 315 may be configured as a single or multi-layered film made of an inorganic material. For example, an inorganic material may be a metal oxide or a metal nitride. Specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂), etc.

The source electrode 330a and the drain electrode 330b are formed on the interlayer insulating film 315. The source electrode 330a and the drain electrode 330b may be configured as a single layer or multiple layers formed of at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The source electrode 330a and the drain electrode 330b are electrically connected respectively to the source region and drain region of the active layer 310.

A planarization layer 317 is formed on the thin film transistor (TFT). The planarization layer 317 is formed to cover the thin film transistor (TFT), thereby eliminating a step caused by the thin film transistor (TFT) and flattening a top surface thereof. The planarization layer 317 may be configured as a single or multi-layered film made of an organic material. An organic material may include general-purpose polymers such as polymethylmethacrylate (PMMA) or polystyrene (PS), polymer derivatives having phenolic groups, acrylic polymers, imide-based polymers, arylether-based polymers, amide-based polymers, fluorine-based polymers, p-xylene-based polymers, vinyl alcohol-based polymers, and blends thereof. Additionally, the planarization layer 317 may be formed as a composite laminate of an inorganic insulating layer and an organic insulating layer.

A first electrode 510 is located on the planarization layer 317. The first electrode 510 may be electrically connected to the thin film transistor (TFT). Specifically, the first electrode 510 may be electrically connected through a contact hole formed in the planarization layer 317 to the drain electrode 330b. The first electrode 510 may have various shapes, and for example, may be formed by being patterned in an island shape. A bank layer 400 defining a pixel area may be disposed on the planarization layer 317. The bank layer 400 may include a receiving recessed part in which micro LEDs ML is received. For example, the bank layer 400 may include a first bank layer 410 in which the receiving recessed part is formed. The height of the first bank layer 410 may be determined by the height and viewing angle of a micro LED ML. The size (width) of the receiving recessed part may be determined by the resolution and pixel density of a display device. In the first embodiment, the height of the micro LED ML may be greater than the height of the first bank layer 410. The receiving recessed part may have a quadrangular cross-sectional shape, but the embodiments of the present disclosure are not limited thereto. The receiving recessed part may have various cross-sectional shapes such as polygonal, rectangular, circular, conical, oval, and triangular shapes.

The bank layer 400 may further include a second bank layer 420 located on the first bank layer 410. A step is formed between the first bank layer 410 and the second bank layer 420, and the width of the second bank layer 420 may be smaller than the width of the first bank layer 410. A conductive layer 550 may be disposed on the second bank layer 420. The conductive layer 550 may be disposed in a direction parallel to a data line or a scan line, and is electrically connected to a second electrode 530. However, the present disclosure is not limited thereto, and the second bank layer 420 may be omitted, and the conductive layer 550 may be disposed on the first bank layer 410. Alternatively, the second bank layer 420 and the conductive layer 550 may be omitted, and the second electrode 530 as a common electrode common to pixels P may be formed on the entirety of the substrate 301. The first bank layer 410 and the second bank layer 420 may include a material absorbing at least a portion of light, a light reflective material, or a light scattering material. The first bank layer 410 and the second bank layer 420 may include an insulating material translucent or opaque to visible light (e.g., light in a wavelength range of 380 nm to 750 nm).

For example, the first bank layer 410 and the second bank layer 420 may be formed of thermoplastic resin such as polycarbonate (PC), polyethylene terephthalate (PET), polyether sulfone, polyvinyl butyral, polyphenylene ether, polyamide, polyetherimide, norbornene system resin, methacryl resin, and cyclic polyolefin resin, thermosetting resin such as epoxy resin, phenol resin, urethane resin, acrylic resin, vinyl ester resin, imide resin, urethane resin, urea resin, and melamine resin, or organic insulating materials such as polystyrene, polyacrylonitrile, and polycarbonate, etc., but are not limited thereto.

For another example, the first bank layer 410 and the second bank layer 420 may be formed of inorganic insulating materials such as an inorganic oxide or an inorganic nitride such as SiOₓ, SiNₓ, SiNxO_{y}, AlOₓ, TiOₓ, TaOₓ, and ZnOₓ, but is not limited thereto. In the first embodiment, the first bank layer 410 and the second bank layer 420 may be formed of an opaque material such as a black matrix material. An insulating black matrix material may include resin or paste including organic resin, glass paste, and black pigment, metal particles such as nickel, aluminum, molybdenum, and alloys thereof, metal oxide particles (e.g., chromium oxide), or metal nitride particles (e.g., chromium nitride). In a modified example, the first bank layer 410 and the second bank layer 420 may be a distributed Bragg reflector (DBR) having high reflectivity or a mirror reflector formed of metal.

A micro LED ML is disposed in the receiving recessed part. The micro LED ML in the receiving recessed part may be electrically connected to the first electrode 510.

Micro LED ML emits light having wavelengths of red, green, blue, and white colors, and may realize white light by using a fluorescent material or combining colors. An individual micro LED ML or a plurality of micro LEDs is picked up on the first substrate 101 by a transfer head (not shown) according to the embodiment of the present disclosure and transferred to the third substrate 301 to be received in the receiving recessed part of the circuit board 301.

The micro LED ML includes a p-n diode, the first contact electrode 106 disposed on one side of the p-n diode, and the second contact electrode 107 located on an opposite side to the first contact electrode 106. The first contact electrode 106 may be connected to the first electrode 510, and the second contact electrode 107 may be connected to the second electrode 530.

The first electrode 510 may include a reflective film formed of Ag, Mg, Al, Pt, Pd, Au, Ni, Nd, Ir, Cr, and a compound thereof, and a transparent or semi-transparent electrode layer formed on the reflective film. A transparent or translucent electrode layer may include at least one selected from a group including indium tin oxide (ITO), indium zinc oxide (IZO), zinc oxide (ZnO), indium oxide (In₂O₃), indium gallium oxide (IGO), and aluminum zinc oxide (AZO).

A passivation layer 520 surrounds a micro LED ML in the receiving recessed part. The passivation layer 520 covers the receiving recessed part and the first electrode 510 by filling space between the bank layer 400 and the micro LED ML. The passivation layer 520 may be formed of an organic insulating material. For example, the passivation layer 520 may be formed of acrylic, polymethyl methacrylate (PMMA), benzocyclobutene (BCB), polyimide, acrylate, epoxy, and polyester, etc., but is not limited thereto.

The passivation layer 520 is formed to have height so as not to cover the upper portion of the micro LED ML, for example, the second contact electrode 107, and thus the second contact electrode 107 is exposed to the outside. The second electrode 530 electrically connected to the exposed second contact electrode 107 of the micro LED ML may be formed on the passivation layer 520.

The second electrode 530 may be disposed on the micro LED ML and the passivation layer 520. The second electrode 530 may be formed of a transparent conductive material such as ITO, IZO, ZnO, or In₂O₃.

In the previous description, a vertical micro LED ML in which the first and second contact electrodes 106 and 107 are provided on the lower and upper surfaces of the micro LED ML, respectively, has been illustrated, but in the exemplary embodiments of the present disclosure, the micro LED may be a flip or lateral type micro LED ML in which both the first and second contact electrodes 106 and 107 are provided on one surface of the upper and lower surfaces of the micro LED ML, and in this case, the first and second electrodes 510 and 530 may also be provided appropriately.

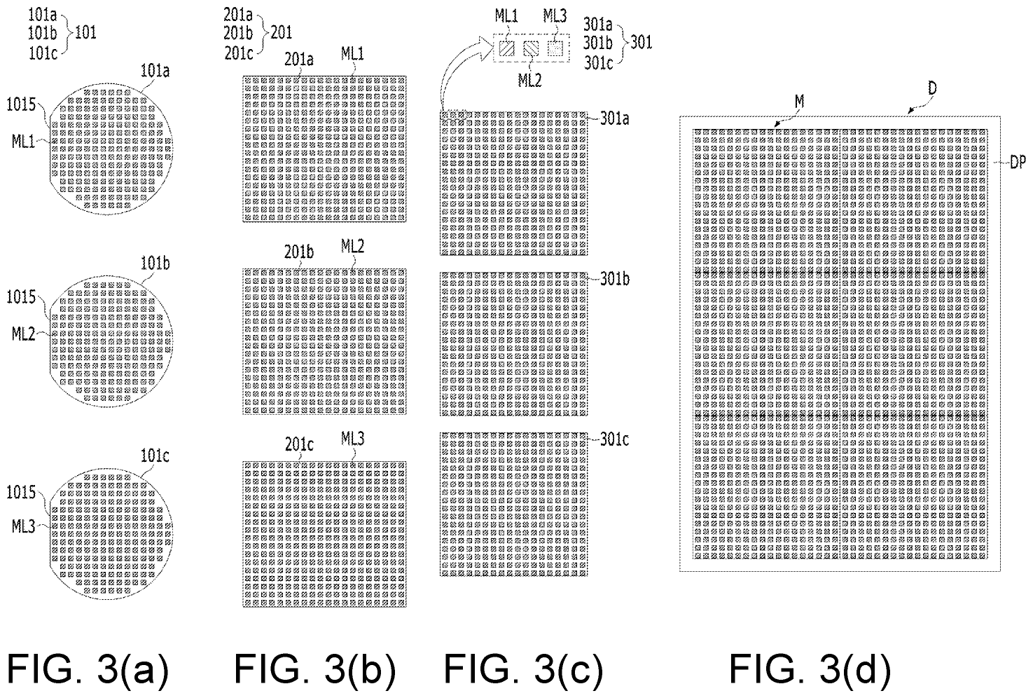

FIG. 3 are views roughly showing the process of manufacturing a micro LED display, which is the background technology of the idea of the present disclosure.

FIG. 3(a) illustrates the step of preparing the first substrate provided with micro LEDs ML. In this case, the first substrate 101, which is the growth substrate in which micro LEDs ML are manufactured, may have curvature in at least a portion of an edge thereof. Additionally, as illustrated in FIG. 3(a), red, green, and blue micro LEDs ML1, ML2, and ML3 are manufactured and prepared in the first substrate 101 (101a, 101b, and 101c) through an epi process. Accordingly, the first substrate 101 may include a plurality of first substrates 101a, 101b, and 101c.

A micro LED to be adsorbed for being transferred from the first substrate 101 onto a second substrate 201 and the third substrate 301 may be any one of a red micro LED ML1, a green micro LED ML2, a blue micro LED ML3, and a white micro LED. The red micro LED ML1, the green micro LED ML2, and the blue micro LED ML3 may go through the second substrate 201 and then may be transferred to the third substrate 301 to be spaced apart from each other so as to form a pixel array. In this case, spacing distances between the red micro LED ML1, the green micro LED ML2, and the blue micro LED ML3 on the third substrate 301 may be determined according to the arrangement of an adsorption area (not shown) in which micro LEDs ML are adsorbed.

Micro LEDs ML are disposed at predetermined distances on the first substrate 101a, 101b, and 101c. Specifically, a plurality of red micro LEDs ML1 is disposed at predetermined distances on one first substrate 101a, a plurality of green micro LEDs ML2 is disposed at predetermined distances on another first substrate 101b, and a plurality of blue micro LEDs ML3 is disposed at predetermined distances on still another first substrate 101c. In this case, spacing distances between the red micro LED ML1, greed micro LED ML2, and blue micro LED ML3 may be the same. In the embodiment, relative to the drawing, the red micro LEDs ML1 are provided at the uppermost side, the blue micro LEDs ML3 are provided at the bottom, and the green micro LEDs ML3 are provided between the red micro LEDs ML1 and the blue micro LEDs ML3, but the order of providing the micro LEDs ML is not limited thereto.

FIG. 3(b) illustrates the step of preparing the second substrate formed into a quadrangular shape. Micro LEDs ML on the first substrate 101 are adsorbed to the transfer head and then are transferred onto the second substrate 201. In this case, the second substrate 201, which is a temporary substrate, may be formed into a quadrangular shape.

The red micro LED ML1, the green micro LED ML2, and the blue micro LED ML3 are transferred respectively to second substrates 201a, 201b, and 201c different from each other. In this case, spacing difference between micro LEDs ML on the first substrate 101 are the same as spacing difference between micro LEDs ML on the second substrate 201.

Specifically, the arrangement of the micro LEDs ML of the first substrate 101 and the arrangement of the micro LEDs ML of the second substrate 201 are provided to be the same. Accordingly, the same luminous properties as luminous properties of the micro LEDs ML of the first substrate 101 may be provided to the second substrate 201. That is, when luminous properties of the micro LEDs ML of the first substrate 101 are not uniform, the luminous properties of the micro LEDs ML of the second substrate 201 to which the micro LEDs ML of the first substrate 101 are transferred in the same arrangement may also be provided so as not to be uniform. In the present disclosure, the method of transferring the micro LEDs from the first substrate 101 to the second substrate 201 for preventing the non-uniformity of the luminous properties of micro LEDs ML will be described later.

FIG. 3(c) illustrates the step of preparing the third substrate in which the pixel array is formed. The micro LEDs ML1, ML2, and ML3 transferred to the second substrate 201 may be adsorbed to the transfer head and then may be transferred to the third substrate 301. In this case, the third substrate 301 is the circuit board and may be formed in the same quadrangular shape as the shape of the second substrate 201.

Micro LEDs ML provided in any one second substrate of a plurality of second substrates 201a, 201b, and 201c may first be transferred to the third substrate 301. For example, the red micro LEDs ML1 may be first transferred to the third substrate 301, and then the green micro LED ML2 may be transferred thereto, and then the blue micro LED ML3 may be transferred thereto.

Specifically, in the second substrate 201a, a plurality of red micro LEDs ML1 provided in a first column at the left side relative to the drawing may first be transferred to a third substrate 301a.

When the red micro LEDs ML1 of the first column are transferred to the third substrate 301a, a plurality of green micro LEDs ML2 provided in a first column in the second substrate 201b may secondly be transferred to the third substrate 301a. That is, the red micro LEDs ML1 are provided in the first column of the third substrate 301a, and the green micro LEDs ML2 may be provided in a second column thereof.

After the green micro LEDs ML2 are transferred to the second column of the third substrate 301a, a plurality of blue micro LEDs ML3 provided in a first column of the second substrate 201c may thirdly be transferred to the third substrate 301a. That is, the blue micro LEDs ML3 may be provided in the third column of the third substrate 301a.

By repeating the above process, the micro LEDs ML may be transferred to the third substrate 301a, 301b, or 301c, and accordingly, the third substrate 301 may form a pixel array. In this case, intervals between micro LEDs ML are the same.

Micro LEDs ML in one column as described above may be repeatedly transferred, but the transferring of micro LEDs ML is not limited thereto. For example, micro LEDs ML in a plurality of columns may be simultaneously transferred.

Specifically, the transfer head may adsorb only micro LEDs ML of the second substrate 201a corresponding to triple pitch intervals and then may transfer the same to the third substrate 301. In this case, the transfer head may adsorb micro LEDs ML located in the 1st, 4th, 7th, and 10th positions of the second substrate 201, and then may transfer the same to the third substrate 301. When the above process is repeatedly applied to the green micro LEDs ML2 and the blue micro LEDs ML3, red micro LEDs ML1 are provided in the 1st, 4th, 7th, and 10th positions of the third substrate 301, green micro LEDs ML2 are provided in the 2nd, 5th, 8th of the third substrate 301, and blue micro LEDs ML3 may be provided in the 3rd, 6th, 9th, and 12th positions of the third substrate 301. That is, the same type of micro LEDs ML are transferred to the same column of the third substrate 301, and each of the micro LEDs ML may have a predetermined pitch interval therebetween.

FIG. 3(d) illustrates the step of preparing the micro LED display. While micro LEDs ML transferred at predetermined pitch intervals onto the third substrate 301 form a pixel array, a unit module M having a specific pixel array may be manufactured.

As an example, a 1×3 pixel array is formed is formed on the third substrate 301 to which micro LEDs ML1, ML2, and ML3 are transferred at predetermined pitch intervals. As the 1×3 pixel array is formed on the third substrate 301, the unit module M having the 1×3 pixel array may be manufactured.

The unit module M may be transferred to a display substrate DP. In other words, a display D may be formed by transferring a plurality of unit modules M to the display substrate DP.

Due to the plurality of unit modules M transferred to the display substrate DP, the pixel array of micro LEDs in the display substrate DP may be the same as the pixel array of micro LEDs in the unit module M. Additionally, the pitch intervals of micro LEDs of the pixel array in the display substrate DP may be the same as the pitch intervals of micro LEDs of the pixel array in the unit module M.

### First Embodiment

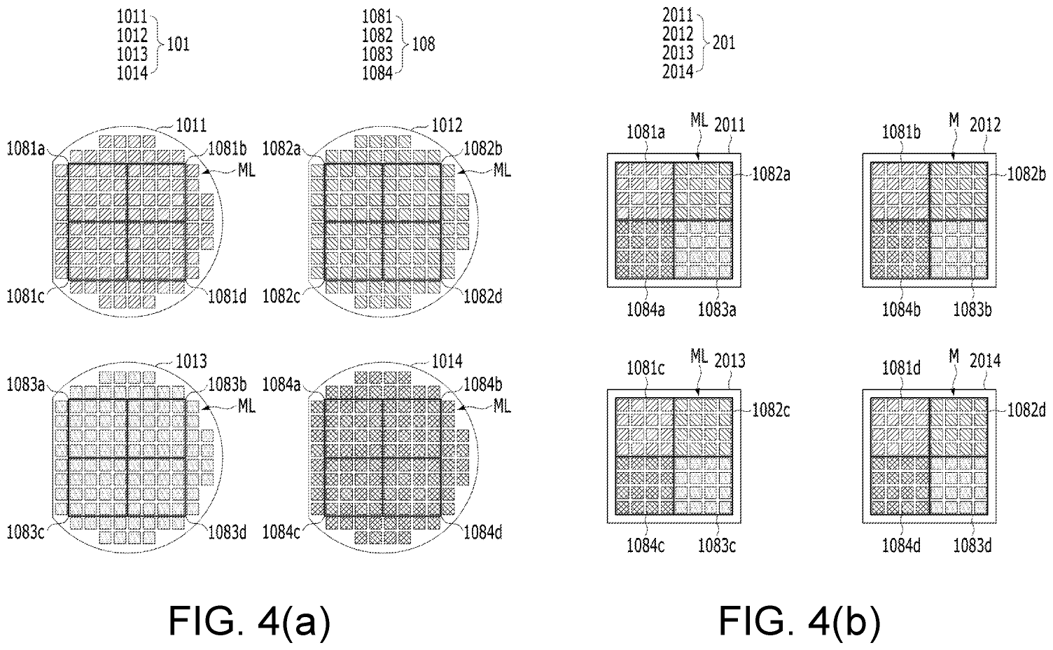

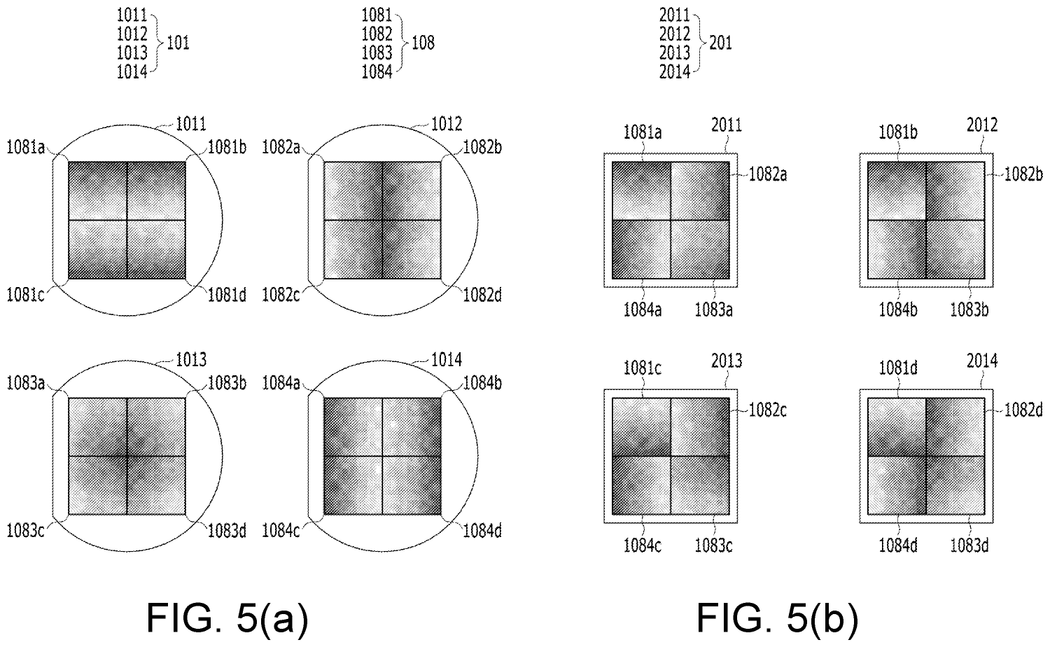

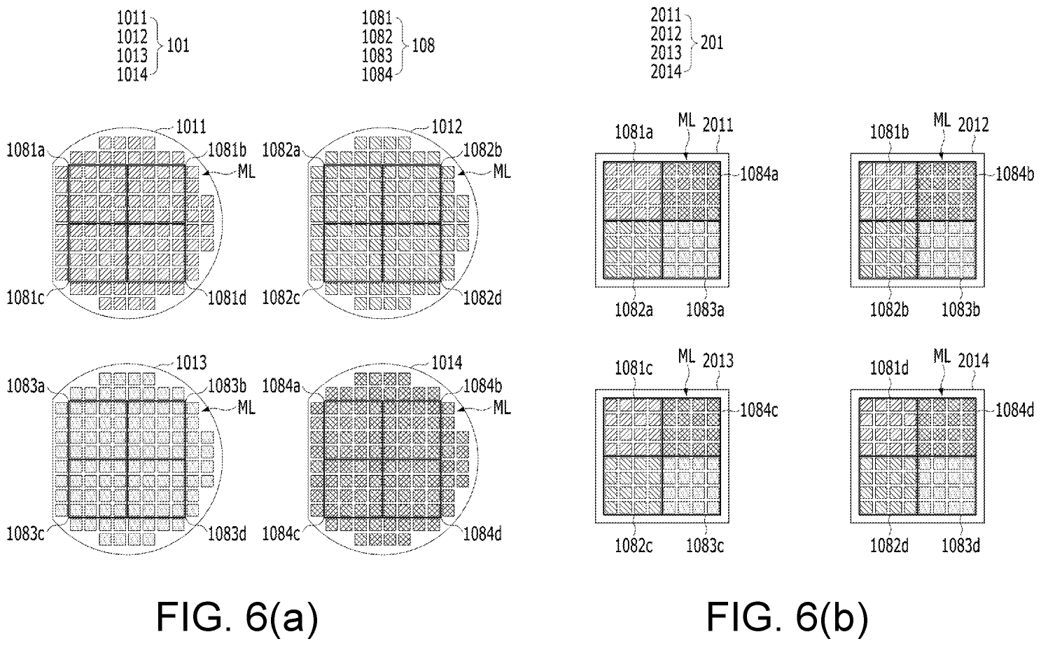

FIG. 4 are views illustrating the appearances of the first substrate and the second substrate according to the exemplary embodiment of the present disclosure, FIG. 5 are views illustrating luminous properties of the micro LEDs of the substrates of FIG. 4 as an example, FIG. 6 are views illustrating modified appearances of FIG. 4. In this case, FIG. 4(a), FIG. 5(a) and FIG. 6(a) are views illustrating the first substrate 101, and FIG. 4(b), FIG. 5(b), and FIG. 6(b) are views illustrating the second substrate 201.

Referring to FIG. 4, the first substrate 101 may be segmented into a plurality of segmented regions 108. For convenience of explanation, FIG. 4 illustrates an example in which four segmented regions 108 are provided on the first substrate 101, but the number of the segmented regions 108 is not limited thereto. Additionally, among a plurality of micro LEDs ML, micro LEDs ML which are not provided in the segmented region 108 are illustrated to be provided, but at least four segmented regions 108 may be provided such that all micro LEDs ML can be provided in the segmented region 108. That is, the first substrate 101 may include the plurality of segmented regions 108, and all micro LEDs ML in the first substrate 101 may be provided in the segmented region 108.

The segmented region 108 is provided to have a polygonal shape, and micro LEDs ML in one segmented region 108 may be simultaneously adsorbed to the transfer head and then transferred to the second substrate 201.

In this embodiment, an example in which the first substrate 101 is provided as a growth substrate and the second substrate 201 is provided as a temporary substrate will be described. However, the types of the first substrate 101 and the second substrate 201 are not limited thereto, and for example, both the first substrate 101 and the second substrate 201 may be provided as temporary substrates.

In order to manufacture the micro LED ML display, the first substrate 101 having the micro LEDs ML of the same color may include a plurality of first substrates. Specifically, each of the first substrates 1011, 1012, 1013, and 1014 illustrated in FIG. 4(a) may include micro LEDs ML having the same colors. For example, when micro LEDs ML provided on the 1-1 substrate 1011 is red micro LEDs ML, micro LEDs ML provided on each of the 1-2 substrate 1012, the 1-3 substrate 1013, and the 1-4 substrate 1014 may be red micro LEDs ML.

In addition, in order to manufacture the micro LED ML display, the second substrate may include a plurality of second substrates 2011, 2012, 2013, and 2014. Specifically, the second substrate 201 is provided in the same number as the first substrate 101, and as illustrated in FIG. 4(b), micro LEDs ML having the same colors may be transferred to the second substrates 2011, 2012, 2013, and 2014. That is, micro LEDs ML of the first substrates 1011, 1012, 1013, and 1014 provided as the same colors may be transferred to the second substrates 2011, 2012, 2013, and 2014, respectively.

Each of the plurality of first substrates 1011, 1012, 1013, and 1014 may be divided into the plurality of segmented regions 1081, 1082, 1083, and 1084. Specifically, the 1-1 substrate 1011 may be divided into a 1-1 segmented region 1081a, a 1-2 segmented region 1081b, a 1-3 segmented region 1081c, and a 1-4 segmented region 1081d, and the 1-2 substrate 1012 may be divided into a 2-1 segmented region 1082a, a 2-2 segmented region 1082b, a 2-3 segmented region 1082c, and a 2-4 segmented region 1082d. Additionally, the 1-3 substrate 1013 may be divided into a 3-1 segmented region 1083a, a 3-2 segmented region 1083b, a 3-3 segmented region 1083c, and a 3-4 segmented region 1083d, and the 1-4 substrate 1014 may be divided into a 4-1 segmented region 1084a, a 4-2 segmented region 1084b, a 4-3 segmented region 1084c, and a 4-4 segmented region 1084d. In this case, the size of each of the segmented regions 1081, 1082, 1083, and 1084 may be the same. Additionally, in the embodiment, each of the segmented regions 1081, 1082, 1083, and 1084 is illustrated to have a quadrangular shape, but the shape of each of the segmented regions 1081, 1082, 1083, and 1084 is not limited thereto.

Micro LEDs ML of each of the segmented regions 1081a, 1081b, 1081c, and 1081d of the 1-1 substrate 1011 may be transferred respectively to second substrates 2011, 2012, 2013, and 2014 different from each other. Specifically, the 1-1 segmented region 1081a may be transferred to a 2-1 substrate 2011, and the 1-2 segmented region 1081b may be transferred to a 2-2 substrate 2012. Additionally, the 1-3 segmented region 1081c may be transferred to a 2-3 substrate 2013, and the 1-4 segmented region 1081d may be transferred to a 2-4 substrate 2014. In this case, the micro LEDs ML of the 1-1 substrate 1011 may be transferred to the corresponding positions of the second substrates 2011, 2012, 2013, and 2014, respectively. For example, when the micro LEDs ML of the 1-1 segmented region 1081a of the 1-1 substrate 1011 are transferred to an upper left part relative to the center of the 2-1 substrate 2011, micro LEDs ML of the 1-2 segmented region 1081b, the 1-3 segmented region 1081c, and the 1-4 segmented region 1081d of the 1-1 substrate 1011 may also be transferred to upper left parts of the 2-2 substrate 2012, the 2-3 substrate 2013, and the 2-4 substrate 2014, respectively, relative to centers of thereof.

Micro LEDs ML of the segmented regions 1082a, 1082b, 1082c, and 1082d of the 1-2 substrate 1012 may be transferred respectively to second substrates 2011, 2012, 2013, and 2014 different from each other, micro LEDs ML of the segmented regions 1083a, 1083b, 1083c, and 1083d of the 1-3 substrate 1013 may be transferred respectively to second substrates 2011, 2012, 2013, and 2014 different from each other, and micro LEDs ML of each of the segmented regions 1084a, 1084b, 1084c, and 1084d of the 1-4 substrate 1014 may be transferred respectively to second substrates 2011, 2012, 2013, and 2014 different from each other. In this case, the micro LEDs ML of the 1-2 substrate 1012, the 1-3 substrate 1013, and the 1-4 substrate 1014 may be transferred to the corresponding positions of the second substrates 2011, 2012, 2013, and 2014.

Specifically, the micro LEDs ML of the 1-1 substrate 1011 may be transferred to the upper left part of each of second substrates 2011, 2012, 2013, and 2014, and the micro LEDs ML of the 1-2 substrate 1012 may be transferred to the upper right part of each of the second substrates 2011, 2012, 2013, and 2014. Additionally, the micro LEDs ML of the 1-3 substrate 1013 may be transferred to the lower right part of each of the second substrates 2011, 2012, 2013, and 2014, and the micro LEDs ML of the 1-4 substrate 1014 may be transferred to the lower left part of each of the second substrates 2011, 2012, 2013, or 2014. In this case, after the micro LEDs ML of the 1-1 substrate 1011 are transferred, the micro LEDs ML of the 1-2 substrate 1012 may be transferred, after the micro LEDs ML of the 1-2 substrate 1012 are transferred, the micro LEDs ML of the 1-3 substrate 1013 may be transferred, and after the micro LEDs ML of the 1-3 substrate 1013 are transferred, the micro LEDs ML of the 1-4 substrate 1014 may be transferred. That is, the micro LEDs ML of the first substrates 1011, 1012, 1013, and 1014 may be sequentially transferred to the second substrate 2011, 2012, 2013, and 2014, respectively. Accordingly, the micro LEDs of a plurality of first substrates 1011, 1012, 1013, and 1014 may be included in the second substrates 2011, 2012, 2013, and 2014, respectively.

In this embodiment, micro LEDs ML of the first substrates 1011, 1012, 1013, and 1014 is illustrated to be sequentially transferred clockwise on the second substrate 2011, 2012, 2013, or 2014, but the array of the LEDs on the second substrate 2011, 2012, 2013, or 2014 is not limited thereto. For example, as illustrated in FIG. 6, the micro LEDs ML of the first substrates 1011, 1012, 1013, and 1014 may be sequentially transferred counterclockwise on the second substrate 2011, 2012, 2013, or 2014.

As micro LEDs ML of the first substrates 1011, 1012, 1013, and 104 are transferred to the second substrates 2011, 2012, 2013, and 2014 so as not to correspond to each other for the segmented regions 1081, 1082, 1083, and 1084, the arrangement of the micro LEDs ML of the first substrates 1011, 1012, 1013, and 1014 may be different from the arrangement of micro LEDs ML of the second substrates 2011, 2012, 2013, and 2014. That is, non-uniformity of luminous properties of micro LEDs ML of the first substrates 1011, 1012, 1013, and 1014 may not appear on the second substrates 2011, 2012, 2013, and 2014.

Specifically, non-uniformity of luminous properties of micro LEDs ML may occur in each of the first substrates 1011, 1012, 1013, and 1014 as illustrated in FIG. 5(a). For example, micro LEDs ML of the first substrates 1011, 1012, 1013, and 1014 may exhibit chromaticities different from each other. Specifically, in the 1-1 substrate 1011, the luminous color of central micro LEDs ML may be brighter than the luminous color of upper and lower micro LEDs ML, and in the 1-2 substrate 1012, the luminous color of central micro LEDs ML may be darker than the luminous color of left and right micro LEDs ML. Additionally, in the 1-3 substrate 1013, the luminous color of central micro LEDs ML may be darker than the luminous color of outer micro LEDs ML, and in the 1-4 substrate 1014, the luminous color of central micro LEDs ML may be brighter than the luminous color of left and right micro LEDs ML. That is, each of the first substrates 1011, 1012, 1013, and 1014 includes micro LEDs ML having the same colors. However, each of the first substrates 1011, 1012, 1013, and 1014 may include micro LEDs ML having different chromaticities for each position.

According to the method for manufacturing a micro LED display which is the background technology of the idea of the present disclosure, the micro LEDs ML of each of the first substrates 1011, 1012, 1013, and 1014 as described above are transferred in the same arrangement onto the second substrates 2011, 2012, 2013, and 2014. Accordingly, when the non-uniformity of luminous properties occurs on the first substrates 1011, 1012, 1013, and 1014 as illustrated in FIG. 5(a), the same non-uniformity of luminous properties as the non-uniformity of luminous properties of the first substrates 1011, 1012, 1013, and 1014 occurs on the second substrates 2011, 2012, 2013, and 2014. In contrast, in this embodiment, according to the method for manufacturing a micro LED display, the first substrates 1011, 1012, 1013, and 1014 are divided into the plurality of segmented regions 1081, 1082, 1083, and 1084, and the micro LEDs ML of each of the segmented regions 1081, 1082, 1083, and 1084 are transferred to and arranged on the second substrates 2011, 2012, 2013, and 2014 different from each other, so non-uniform luminous properties of the first substrates 1011, 1012, 1013, and 1014 may not occur in the second substrates 2011, 2012, 2013, and 2014. Specifically, as illustrated in FIG. 5(b), in each of the second substrates 2011, 2012, 2013, and 2014, micro LEDs ML having different chromaticities may spread without being concentrated on one side. Accordingly, in this embodiment, micro LEDs ML of the first substrates 1011, 1012, 1013, and 1014 are transferred to the second substrates 2011, 2012, 2013, and 2014 in different arrangement, thereby preventing non-uniformity of luminous properties of micro LEDs ML.

In addition, micro LEDs ML of one segmented region 1081, 1082, 1083, or 1084 are simultaneously transferred to the second substrates 2011, 2012, 2013, and 2014, and thus time required for the transferring may be reduced compared to when micro LEDs ML of the first substrates 1011, 1012, 1013, and 1014 are individually transferred.

### Second Embodiment

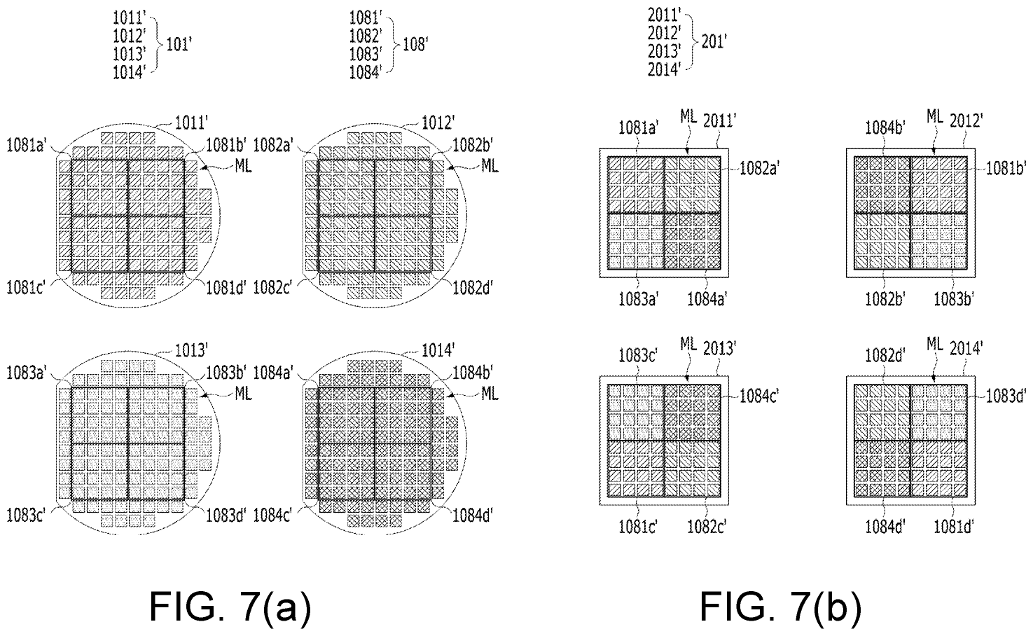

FIG. 7 are views illustrating the appearances of the first substrate and the second substrate of FIG. 4, respectively, according to the second embodiment. When the second embodiment is compared to the first embodiment, the second embodiment has the array of micro LEDs ML of a second substrate 201′ different from the array of micro LEDs of the second substrate of the first embodiment, so the difference will be mainly described, and the description and reference numerals of the first embodiment will be used for the same parts.

Referring to FIG. 7, micro LEDs ML of a first substrate may be transferred to each of second substrates 2011′, 2012′, 2013′, and 2014′ in different arrangement. Specifically, micro LEDs ML of one first substrate 1011′, 1012′, 1013′, or 1014′ may be transferred to the non-corresponding position of each of the second substrates 2011′, 2012′, 2013′, and 2014′. For example, when micro LEDs ML of a 1-1 segmented region 1081a′ of the 1-1 substrate 1011′ are transferred to the upper left part of the 2-1 substrate 2011′, micro LEDs ML of a 1-2 segmented region 1081b′ of the 1-1 substrate 1011′ may be transferred to the upper right part of the 2-2 substrate 2012′ instead of the upper left part thereof. Additionally, when micro LEDs ML of a 1-3 segmented region 1081c′ are transferred to the lower left part of the 2-3 substrate 2013′, the micro LED ML of a 1-4 segmented region 1081d′ may be transferred to the lower right part of the 2-4 substrate 2014′.

In addition, micro LEDs ML of each of segmented regions 1082a′, 1082b′, 1082c′, and 1082d′ of the 1-2 substrate 1012′ may be transferred to the non-corresponding position of each second substrate 2011′, 2012′, 2013′, or 2014′, micro LEDs ML of each of the segmented regions 1083a′, 1083b′, 1083c′, and 1083d′ of the 1-3 substrate 1013′ may be transferred to the non-corresponding position of each second substrate 2011′, 2012′, 2013′, or 2014′, micro LEDs ML of each of the segmented regions 1084a′, 1084b′, 1084c′, and 1084d′ of the 1-4 substrate 1014′ may be transferred to the non-corresponding position of each second substrate 2011′, 2012′, 2013′, or 2014′. Accordingly, micro LEDs ML may be transferred to each second substrate 2011′, 2012′, 2013′, or 2014′ in different arrangement. For example, the micro LEDs ML of the 1-1 substrate 1011′ may be transferred to the upper left part of the 2-1 substrate 2011′, and micro LEDs ML of the 1-4 substrate 1014′ may be transferred to the upper left part of the 2-2 substrate 2012′. Additionally, micro LEDs ML of the 1-3 substrate 1013′ may be transferred to the upper left part of the 2-3 substrate 2013′, and micro LEDs ML of the 1-2 substrate 1012′ may be transferred to the upper left part of the 2-4 substrate 2014′.

Micro LEDs ML of each of the first substrates 1011′, 1012′, 1013′, and 1014′ are transferred to each second substrate 2011′, 2012′, 2013′, or 2014′ in different arrangement, so even if non-uniformity of luminous properties appears in any one of the second substrates 2011′, 2012′, 2013′, and 2014′, the non-uniformity of luminous properties may be prevented from appearing in the entirety of the second substrates 2011′, 2012′, 2013′, and 2014′.

As described above, micro LEDs ML grouped and transferred to the second substrate are transferred from the first substrates different from each other, so a predetermined pattern of luminous properties in the first substrates may be partially relieved in the second substrate.

Above, the method for manufacturing a micro LED display according to the embodiments of the present disclosure has been described as specific embodiments, but this is only for illustrative purpose, and the present disclosure is not limited thereto, and should be construed as having the widest scope according to a basic idea disclosed herein. Those skilled in the art may implement a pattern of a shape not indicated by combining and substituting the disclosed embodiments, but this also does not depart from the scope of the present disclosure. In addition, those skilled in the art can easily change or modify the disclosed embodiments based on the present specification, and it is clear that such a change or modification also falls within the scope of the present disclosure.

### DESCRIPTION OF THE REFERENCE NUMERALS IN THE DRAWINGS

101, 101′: First substrate 102: First semiconductor layer
103: Active layer 104: Second semiconductor layer
106: First contact electrode 107: Second contact electrode
108, 108′: Segmented region 201, 201′: Second substrate
301: Circuit board

What is claimed is:

1. A method for manufacturing a micro LED display, the method comprising:
a step of preparing a plurality of first substrates having a plurality of micro LEDs;
a step of preparing a plurality of second substrates;
a segmented region formation step of segmenting each of the first substrates into a plurality of regions; and
a step of transferring micro LEDs of each of the segmented regions of each of the first substrates to each of the second substrates,
wherein one of the second substrates comprises micro LEDs of the plurality of first substrates.

2. The method of claim 1, wherein the micro LEDs of each of the segmented regions of each of the first substrates are sequentially transferred to a corresponding position of each of the second substrates.

3. The method of claim 1, wherein the micro LEDs of each of the segmented regions of each of the first substrates are sequentially transferred to a non-corresponding position of each of the second substrates.
